(19) United States
(12) Patent Application Publication
(10) Pub. No.: US 2016/0161584 A1
(43) Pub. Date: Jun. 9, 2016

(54) METHOD FOR THE RECONSTRUCTION OF MAGNETIC RESONANCE IMAGE DATA

(71) Applicant: Siemens Aktiengesellschaft, Muenchen (DE)

(72) Inventors: Hans-Peter Fautz, Forchheim (DE); Michael Koehler, Nuernberg (DE); Marcel Dominik Nickel, Herzogenaurach (DE); Rainer Schneider, Erlangen (DE); Mario Zeller, Erlangen (DE)

(73) Assignee: Siemens Aktiengesellschaft, Muenchen (DE)

(21) Appl. No.: 14/963,666

(22) Filed: Dec. 9, 2015

(30) Foreign Application Priority Data
Dec. 9, 2014 (DE) 102014225299.7

(51) Int. Cl. G01R 33/56; G01R 33/48; G06F 19/00

(52) U.S. Cl. CPC G01R 33/5607; G06F 19/321; G01R 33/4828; G01R 33/5608

(57) ABSTRACT

In a method and apparatus for the reconstruction of magnetic resonance image data, magnetic resonance measurement data are acquired from an object under examination by a Dixon recording technique. A model is provided to a computer, the model including modeling data matched to the object under examination from which the magnetic resonance measurement data were acquired. At least one tissue image is reconstructed in the computer from the magnetic resonance measurement data using the model matched to the object under examination, wherein the at least one tissue image includes at least one fat image and/or at least one water image.

### BACKGROUND OF THE INVENTION

1. Field of the Invention

The invention concerns a method for the reconstruction of magnetic resonance image data, and a computer and storage medium for implementing such a method.

2. Description of the Prior Art

In a magnetic resonance device, also called a magnetic resonance tomography system, the body of a person under examination, in particular a patient, is conventionally exposed to a relatively high basic magnetic field, for example of 1.5 or 3 or 7 tesla with the use of a basic field magnet. In addition, gradient switchings are produced with a gradient coil unit. Radio-frequency pulses, for example excitation pulses, are then emitted by a radio-frequency antenna unit via suitable antenna systems, and this causes the nuclear spins of specific atoms, which are resonantly excited by these radio-frequency pulses, to be tilted by a defined flip angle with respect to the magnetic field lines of the basic magnetic field. Upon relaxation of the nuclear spins, radio-frequency signals, called magnetic resonance signals, are emitted, and are received by suitable radio-frequency antennas, and then processed further. Finally, the desired image data can be reconstructed from the raw data acquired in this way.

For a specified measurement (data acquisition), therefore, a specific magnetic resonance sequence, also called a pulse sequence, is emitted, which is composed of a sequence of radio-frequency pulses, for example excitation pulses, preparation pulses and refocusing pulses and compatible therewith, gradient fields are emitted coordinated therewith in different gradient axes in different spatial directions. Readout windows are set coordinated therewith in terms of time that specify the time frames in which the induced magnetic resonance signals are acquired.

Those skilled in the art are familiar with magnetic resonance sequences that provide a Dixon recording technique for the acquisition of magnetic resonance measurement data. The Dixon recording technique is typically used to separately visualize adipose tissue and aqueous tissue in the body of an object under examination. For this purpose, the Dixon recording technique utilizes the different resonant frequencies of protons in the adipose tissue and aqueous tissue.

### SUMMARY OF THE INVENTION

An object of the invention is to provide a procedure that is particularly advantageously matched to the object under examination for the reconstruction of magnetic resonance from image data magnetic resonance measurement data acquired by execution of a Dixon recording technique.

This object is achieved by the method according to the invention for the reconstruction of magnetic resonance image data that includes the following steps.

Magnetic resonance measurement data of an object under examination are acquired by execution of a Dixon recording technique in a scanner.

A computer is provided with a model including modeling data matched to the object under examination from which the magnetic resonance measurement data are acquired.

At least one tissue image is reconstructed from the magnetic resonance measurement data using the model matched to the object under examination, wherein the at least one tissue image includes at least one fat image and/or at least one water image.

The object under examination can be a patient, a person used for training purposes or a phantom. The reconstructed at least one fat image and/or water image is in particular made available, i.e. displayed to a user on a display unit and/or stored in a database. The at least one tissue image in particular highlights at least one specific tissue of the object under examination. Here, the at least one fat image in particular highlights an adipose tissue of the object under examination, wherein an aqueous tissue of the object under examination is suppressed. The at least one water image in particular highlights an aqueous tissue of the object under examination, wherein an adipose tissue of the object under examination is suppressed. The at least one tissue image can also depict further tissue types. However, in a usual case, the at least one tissue image exclusively includes the at least one fat image and/or at least one water image. The following will also be based on this case as an example.

Magnetic resonance measurement data can be acquired, for example, by the application of phase encoding gradients and frequency encoding gradients and recording the resulting magnetic resonance signals by a radio-frequency coil. Hence, the magnetic resonance measurement data are typically not directly available to a skilled person for the diagnosis. Instead, the method according to the invention provides a procedure, wherein at least one fat image and/or water image is reconstructed from the magnetic resonance measurement data acquired, which can be depicted on a display unit and/or made available to a skilled person making a diagnosis.

The Dixon recording technique for the acquisition of the magnetic resonance measurement data is advantageously a 2-point Dixon recording technique. Due to its speed and insensitivity to movements of the object under examination associated therewith, the 2-point Dixon recording technique is usually a preferred Dixon recording technique. For example, the 2-point Dixon recording technique in particular provides the acquisition of at least one first magnetic resonance image (in-phase image) with an in-phase fat-water signal and at least one second magnetic resonance image (opposed-phase image) with an out-of-phase fat-water signal, in particular shifted by 180°. For the acquisition of the at least one second magnetic resonance image, it is possible, for example, to switch another readout gradient than for the acquisition of the first magnetic resonance image in order to achieve the phase shift between the fat signal and the water signal. The at least one first magnetic resonance image and the at least one second magnetic resonance image can then be processed together so that at least one fat image and/or water image can be reconstructed from the at least one first magnetic resonance image and at least one second magnetic resonance image. In this case, the post-processing of the at least one first magnetic resonance image and the at least one second magnetic resonance image can provide, in particular weighted, addition and/or subtraction of the at least one first magnetic resonance image and the at least one second magnetic resonance image. In this case, the post-processing of the at least one first magnetic resonance image and the at least one second magnetic resonance image can require phase correction, also known as phase unwrapping, of the at least one first magnetic resonance image and/or the at least one second magnetic resonance image. The 2-point Dixon recording technique is known to the person skilled in the art so that this will not be dealt with in any more detail here.

It should be mentioned that the invention is not restricted to the 2-point Dixon recording technique. It is, for example, also possible to use a 1-point Dixon recording technique known to the person skilled in the art or a 3-point Dixon recording technique known to the person skilled in the art, which provides for the acquisition of three magnetic resonance images, for the acquisition of the magnetic resonance measurement data. It should also be mentioned that the magnetic resonance measurement data in particular includes the at least one first magnetic resonance image and the at least one second magnetic resonance image. The magnetic resonance measurement data in particular does not include the at least one fat image and/or the at least one water image, which is instead to be reconstructed from the magnetic resonance measurement data. Reference is made to the fact that the model is advantageously not used with the aforementioned phase correction of the at least one first magnetic resonance image and the at least one second magnetic resonance image. Instead, the model should advantageously be used for the reconstruction of the at least one fat image and/or water image from the at least one phase-corrected first magnetic resonance image and the at least one phase-corrected second magnetic resonance image. Before the reconstruction of the at least one fat image and/or water image, therefore, in particular phase correction of the magnetic resonance measurement data is performed, wherein phase-corrected magnetic resonance measurement data is generated, wherein the at least one fat image and/or water image is reconstructed from the phase-corrected magnetic resonance measurement data.

The provision of the model can include the loading of a prespecified model from a database, wherein then the modeling data are adapted to the object under examination. The provision of the model can also include a generation of the model, in particular on the basis of object-under-examination parameters acquired from the object under examination. The modeling data are acquired specifically for the object under examination from which the magnetic resonance image data is acquired. The modeling data can also be already matched to the object under examination from which the magnetic resonance measurement data is acquired. In this case, the modeling data can depict a body-specific property assigned to the object under examination. In this way, the modeling data are typically different for different objects under examination, which are examined by means of the magnetic resonance device. The modeling data are acquired from the object under examination when the object under examination is positioned within the magnetic resonance devices for the acquisition of the magnetic resonance image data. In this case, the modeling data can characterize an influence of the object under examination on the acquisition of the magnetic resonance image data. For example, the modeling data can define boundary conditions under which the magnetic resonance image data is acquired.

However, the modeling data are not specified by a user during the setting of the magnetic resonance sequence. For example, the modeling data are different from sequence parameters of the magnetic resonance sequence, which are typically prespecified by a user. For example, the modeling data do not include settings such as the setting of an imaging area (recording volume, field of view, FOV) of the magnetic resonance sequence, even when this imaging area has been adapted to the object under examination.

The model with the modeling data matched to the object under examination can be inserted as an input parameter into an algorithm by means of which the at least one fat image and/or the at least one water image is reconstructed. The at least one fat image and/or the at least one water image can also be reconstructed within at least one boundary condition, wherein the at least one boundary condition is advantageously based on the model matched to the object under examination. The reconstruction of the at least one fat image and/or water image from the magnetic resonance measurement data can in particular be performed using at least one piece of additional information obtained from the model matched to the object under examination.

Preferably, the model matched to the object under examination includes information on the distribution of different tissue types, in particular adipose tissue and/or aqueous tissue, of the object under examination. In this way, the reconstruction of the at least one fat image and/or water image can particularly advantageously be based on the model, as will be described in one of the following sections. It is particularly advantageous to assign fat signals and/or water signals to the magnetic resonance measurement data using the model. In this case, the model matched to the object under examination can represent a starting point on which the assignment of the fat signals and/or water signals to the magnetic resonance measurement data can be based. Various possibilities for using the model matched to the object under examination in the reconstruction of the at least one fat image and/or water image are described in the following sections. For example, a comparison of at least one calculated provisional fat image and/or water image with the model is conceivable. It is also conceivable for the model to be inserted directly into a probability calculation for the assignment of fat signals and/or water signals.

The procedure according to the invention is based on the recognition that, with the Dixon recording technique, an unambiguous assignment of fat signals and/or water signals to the magnetic resonance measurement data, exclusively by the use of the magnetic resonance measurement data, can frequently be defective. With the 2-point Dixon recording technique, an unambiguous separation between fat signals and water signals in the magnetic resonance measurement data acquired is not possible. One possible reason for this the fact that magnetic resonance measurement data acquired by the 2-point Dixon recording technique typically include only two magnetic resonance images, with which a global frequency offset and a frequency shift between fat signals and water signals cannot be taken into account separately. With such a conventional reconstruction of the at least one fat image and/or water image solely using magnetic resonance measurement data, there may be incorrect assignments of fat signals and/or water signals to the magnetic resonance measurement data. For example, an incorrect assignment decision can result in a global transposition of the at least one fat image and at least one water image. One reason for this can be an unknown global frequency offset and/or phase offset applicable to all voxels of the magnetic resonance measurement data in the magnetic resonance measurement data. Another possible source of the ambiguity is the local spatially limited transposition of fat signals and water signals, for example due to local phase inconsistencies, with a conventional reconstruction of the at least one fat image and/or water image. This can occur, for example, when a region-growing algorithm is used, be propagated into further image areas of the at least one fat image and/or water image.

The use of the model matched to the object under examination in the reconstruction of the at least one tissue image can enable an, in particular unambiguous, assignment of fat signals and/or water signals to the magnetic resonance measurement data. In particular, the procedure according to the invention enables a local transposition of water signals and fat signals and/or a global transposition of the at least one fat image and/or water image to be avoided at least partially, advantageously for the most part or completely. In this way, it is possible to improve image quality and/or reliability of the at least one fat image and/or water image. In particular, it is possible to reduce, or advantageously completely avoid, artifacts in the at least one fat image and/or water image. The skilled viewer of the at least one fat image and/or water image reconstructed according to the invention can particularly advantageously rely on the fact that the at least one fat image and/or the at least one water image depicts the correct tissue type of the object under examination. A further, possibly complex, consistency check on the at least one fat image and/or water image can particularly advantageously be dispensed with.

In an embodiment, the modeling data originate from further objects under examination, which are different from the originally-noted object under examination, wherein the modeling data are adapted to the object under examination. The further objects under examination do not include the object under examination from which the magnetic resonance measurement data are acquired and to which the modeling data are to be adapted. The modeling data are modeling image data recorded previously from the further objects under examination. This means that the modeling data advantageously describe a tissue distribution, in particular of fat tissue and/or aqueous tissue, in the further object under examination. The modeling data that originate from the further objects under examination can be stored as an atlas. It is possible for the modeling data to depict an averaging of image data from a number of further objects under examination. The modeling data, in particular the atlas, can be stored in a central database connected to a number of magnetic resonance devices with respect to data exchange or in a local database connected to a specific magnetic resonance device with respect to data exchange. This enables the modeling data, in particular the atlas, to be loaded from the central database or local database for the reconstruction of the at least one fat image and/or water image.

The adaptation of the modeling data to the object under examination can include registration and/or reformation and/or resealing of the modeling data. The modeling data are adapted to the object under examination such that the adapted modeling data are present in a similar format to that of the at least one, in particular provisional, fat image and/or water image. In this way, it is particularly simple to perform a comparison as described above, between the modeling data and the at least one provisional fat image and/or water image. The modeling data for the further objects under examination can provide particularly advantageous additional information for a broad patient population, which can be taken into account in the reconstruction of the at least one fat image and/or water image and/or which enables the reconstruction of the at least one fat image and/or water image to be checked.

In an embodiment the modeling data include modeling of the distribution of adipose tissue and/or aqueous tissue. The modeling of the distribution can depict a spatial distribution of the adipose tissue and/or aqueous tissue. The modeling of the distribution can be derived from modeling data obtained from the further objects under examination described in the previous section. The modeling of the distribution can also be performed on the basis of the magnetic resonance measurement data of the object under examination. This enables an assumption for a distribution of the adipose tissue and/or aqueous tissue to be prespecified in the modeling of the distribution. The modeling of the distribution does not represent the actual distribution of the fat tissue and/or aqueous tissue in the object under examination. However, the modeling of the distribution can represent an advantageous starting point for the reconstruction of the actual distribution of the adipose tissue and/or aqueous tissue in the object under examination. For example, a comparison between the at least one provisional fat image and/or the at least one provisional water image with the model as described in one of the following sections can include a comparison of the modeling of the distribution of the adipose tissue and/or aqueous tissue with a distribution of the adipose tissue and/or aqueous tissue in the at least one provisional fat image and/or the at least one provisional water image. The modeling of the distribution of the adipose tissue and/or aqueous tissue can also be used directly in a first assignment of the fat information and/or water information to the magnetic resonance measurement data. The modeling of the distribution can enable particularly easy detection of inconsistencies in a provisional reconstructed fat image and/or water image.

One embodiment provides that the acquisition of the magnetic resonance measurement data includes the acquisition of at least one first magnetic resonance image with an in-phase fat-water signal and at least one second magnetic resonance image with an out-of-phase fat-water signal, wherein the modeling data include the first magnetic resonance image and/or second magnetic resonance image. In particular, the at least one first magnetic resonance image and the at least one second magnetic resonance image can be acquired by a 2-point Dixon recording technique as described in one of the previous sections. The at least one first magnetic resonance image then in particular represents the in-phase image and the at least one second magnetic resonance image the opposed-phase image.

The at least one first magnetic resonance image and/or at least one second magnetic resonance image can be integrated in the model as modeling data. In this way, the model is particularly advantageously matched to the object under examination. In this way, the model is in particular generated specifically for the object under examination. Furthermore, it is advantageously possible to dispense with additional recordings for the modeling data since the at least one first magnetic resonance image and/or second magnetic resonance image is usually acquired as standard by the Dixon recording method. To take account of the at least one first magnetic resonance image and/or second magnetic resonance image in the reconstruction of the at least one fat image and/or water image, it can be advantageous to process the at least one first magnetic resonance image and/or second magnetic resonance image further. A possible further-processing method, namely the segmentation of an organ, is described below.

In another embodiment, at least one provisional tissue image is reconstructed from the magnetic resonance measurement data, wherein the at least one provisional tissue image includes at least one provisional fat image and/or at least one provisional water image. A comparison is performed between the at least one provisional tissue image with the modeling data and the reconstruction of the at least one tissue image is performed using a result of the comparison. The at least one provisional fat image and/or water image can be reconstructed from the magnetic resonance measurement data by a conventional method. It is conceivable for the model matched to the object under examination to be left out of account in the reconstruction of the at least one provisional fat image and/or water image. The at least one provisional fat image and/or water image can in particular be reconstructed using a standard model, which is different from the model and not matched to the object under examination. The at least one provisional fat image and/or water image is not provided directly after the reconstruction, i.e. not displayed to a user and/or stored in a database.

Instead, the at least one provisional fat image and/or water image should be compared in advance with the model. For example, the modeling data of the model matched to the object under examination can include modeling image data with which the at least one provisional fat image and/or water image are compared. In this case, the modeling image data can include an expected distribution of adipose tissue and/or aqueous tissue. The result of the comparison can include a comparison parameter that assesses a sufficient validity and/or freedom from artifacts of the at least one provisional fat image and/or water image. For example, sufficient validity and/or freedom from artifacts of the at least one provisional fat image and/or water image can be provided when the at least one provisional fat image and/or water image consistently conforms to the modeling data. If the comparison parameter has a sufficient value, for example if it is above a prespecified threshold value, the at least one provisional fat image and/or water image can be set directly as the actual fat image and/or water image to be provided. If the comparison parameter is unsatisfactory, the at least one provisional fat image and/or water image can, in particular using the model, be adapted and/or reconstructed once again. The comparison parameter can in particular be unsatisfactory when the comparison of the at least one provisional fat image and/or water image with the modeling data reveals that global and/or local transpositions of fat signals and water signals are present in the at least one provisional fat image and/or water image.

This can enable a highly error-free reconstruction of the at least one fat image and/or water image using the result of the comparison in a particularly simple way. The comparison between the model and the at least one provisional fat image and/or water image can be performed globally over the entire at least one provisional fat image and/or water image. It is also conceivable for said comparison alternatively or additionally to be performed locally, which means in a spatially limited area of the at least one fat image and/or water image. The comparison parameter can then have a local reliability index describing a local spatially limited reliability of the provisional reconstruction of the provisional fat image and/or water image. The subsequent comparison for the checking of the provisional fat image and/or water image represents a particularly simple and fast method for ensuring consistent reconstruction of the at least one fat image and/or water image.

In another embodiment, the reconstruction of the at least one tissue image includes an assignment of fat information and/or water information to the magnetic resonance measurement data using the modeling data. The assignment of the fat information and/or water information to the magnetic resonance measurement data can include an assignment of fat signals and/or water signals to the magnetic resonance measurement data. In this case, the model matched to the object under examination can in particular be used to determine whether magnetic resonance signals included by the magnetic resonance measurement data should be assigned to fat signals and/or water signals. This means that it is possible to determine whether the magnetic resonance signals originate from adipose tissue and/or aqueous tissue of the object under examination. The model matched to the object under examination can be particularly suitable for this because by means of the model, it is possible to check an assignment that has already been made and/or, because the model can provide valuable additional information, such as a starting point for the assignment, during the assignment.

In another embodiment, the modeling data include the segmentation of at least one organ in the magnetic resonance measurement data, wherein the assignment of the fat information and/or water information to the magnetic resonance measurement data is performed using the at least one segmented organ. Similarly, it is also conceivable for at least one organ to be segmented in the modeling data originating from the further objects under examination. In particular, an organ of this kind is segmented in the at least one first magnetic resonance image and/or second magnetic resonance image from which an assignment to adipose tissue or aqueous tissue is known. Possibilities for the segmentation of the at least one organ are known to the person skilled in the art and so they will not be dealt with in any more detail here. For example, it is particularly simple, during a comparison of the provisional reconstructed fat images and/or water images with the model, to determine an inconsistency between the segmented organ in the at least one first magnetic resonance image and/or second magnetic resonance image and a corresponding tissue assignment in the provisional reconstructed fat image and/or water image. The segmented organ can also be inserted directly in the reconstruction of the at least one fat image and/or water image. For example, it is possible to use the segmented organ to restrict and/or identify potential areas for the presence of a fat signal and/or water signal in the magnetic resonance measurement data.

In another embodiment, the modeling data include a B0 distribution of the object under examination. A B0 distribution is typically acquired before the acquisition of the magnetic resonance measurement data from the object under examination. The acquisition of the B0 distribution can include a measurement of a field distribution of the basic magnetic field, also called a B0 field, of the magnetic resonance device. The B0 distribution is measured when the object under examination is introduced into a patient receiving area of the magnetic resonance device. Taking into account the B0 distribution, it is usual to determine shim settings by means of which a shim unit is controlled in order to achieve the best possible homogeneity of the basic magnetic field. Here, the B0 distribution is also called a B0 map or B0 field map. The B0 distribution is particularly advantageously suitable as modeling data since it is usually acquired as standard before the acquisition of the magnetic resonance measurement data and is particularly advantageously matched to the object under examination.

In another embodiment, at least one provisional tissue image is reconstructed from the magnetic resonance measurement data, wherein the at least one provisional tissue image includes at least one provisional fat image and/or at least one provisional water image, a correction map is generated from the at least one provisional tissue image, a correction of the B0 distribution of the object under examination is performed using the correction map, wherein a corrected B0 distribution is calculated, an analysis of the corrected B0 distribution is performed and the reconstruction of the at least one tissue image is performed using a result of the analysis. In this case, the correction map can in particular include phase corrections and/or frequency corrections which are obtained from the reconstructed at least one provisional fat image and/or at least one provisional water image. Following this, the correction map can be applied to the acquired B0 distribution. In this case, the B0 distribution is advantageously recorded following a shim process. The analysis of the corrected B0 distribution can include the determination of discrete jumps in the corrected B0 distribution. Here, the discrete jumps typically occur between different tissue types with different resonant frequencies of protons. If discrete jumps are identified in the corrected B0 distribution it may be concluded that there is a local or global inconsistency of the at least one provisional fat image and/or at least one provisional water image. This may result, for example, in a new reconstruction of the at least one provisional fat image and/or at least one provisional water image. If the analysis of the corrected B0 distribution has revealed that the corrected B0 distribution is flat, i.e. in particular does not have any discrete jumps, the at least one provisional fat image and/or at least one provisional fat image can be set as the final fat image and/or water image of the reconstruction.

In a further embodiment, the modeling data include a mask marking the presence of adipose tissue or aqueous tissue in the object under examination. The mask can be, for example, a fat mask marking the presence of adipose tissue in the object under examination. In this case, the mask can be a binary mask. For example, in the fat mask, the voxels which, with a high degree of probability, contain a significant proportion of fat, can be marked with the value “one”. Simultaneously, the fat mask can also mark the voxels, which, with a high degree of probability, contain a significant proportion of aqueous tissue, with the value “zero”. During the assignment of the fat signals to the magnetic resonance measurement data, the fat mask can be used in such a way that only those voxels in the fat mask with a value of one are inserted into the assignment algorithm. This means in particular that, first, aqueous tissue can be excluded during the assignment. The use of the fat mask or water mask in the reconstruction of the at least one tissue image can enable an, in particular unambiguous, assignment of fat signals to the magnetic resonance measurement data or increase the precision of the assignment. Similarly, this can simplify the assignment of the water signals. In this way, the mask can particularly advantageously represent a priori information for the reconstruction of the at least one tissue image, particularly when using an intensity-based assignment. If the resolutions or image alignment of the mask and the magnetic resonance measurement data acquired by means of the Dixon recording technique are different, the mask can be adapted to the magnetic resonance measurement data, for example by means of interpolation. Furthermore, similarly, obviously the mask can also be a water mask marking the presence of aqueous tissue in the object under examination. Then, the features described for the fat mask can also be transferred to the water mask. The water mask can, for example, be generated by means of pre-measurement with water excitation. The fat mask described can also be generated by the inversion of the water mask. Obviously, the water mask can also be used directly in the reconstruction of the tissue image.

In another embodiment, the mask is generated by a spatially-resolved measurement of a resonant frequency in the object under examination. This procedure is based on the consideration that, with the same static magnetic field, protons in the adipose tissue and protons in the aqueous tissue have different resonant frequencies, shifted by approximately 3.4 ppm. In this way, the spatially-resolved measurement of the resonant frequency can be used to determine the regions in the object under examination in which predominantly aqueous tissue or adipose tissue is present. In this case, the spatially resolved measurement of the resonant frequency can be performed while the object under examination is positioned in the magnetic resonance device for the acquisition of the magnetic resonance measurement data by means of the Dixon recording technique. The spatially resolved measurement of the resonant frequency can in particular be performed chronologically before the acquisition of the magnetic resonance measurement data in a pre-measurement. For example, the measured data used for the generation of a B0 distribution in the object under examination can also be used for the provision of a spatially-resolved distribution of the resonant frequency. Similarly, the spatially resolved measurement of the resonant frequency can obviously also be formed from two measurements with lower resolution, in particular without spectral fat saturation.

The computer system according to the invention includes a measurement-data-acquisition unit (scanner), a provisioning unit (database) and a reconstruction unit (processor), wherein the computer system is configured to carry out a method according to the invention.

Hence, the computer system according to the invention is embodied to carry out a method for the reconstruction of magnetic resonance image data. The measurement-data-acquisition unit is embodied for the acquisition of magnetic resonance measurement data of an object under examination by means of a Dixon recording technique. The provisioning unit is embodied for the provision of a model, which includes modeling data matched to the object under examination from which the magnetic resonance measurement data is acquired. The reconstruction unit is embodied for the reconstruction of at least one tissue image from the magnetic resonance measurement data using the model matched to the object under examination, wherein the at least one tissue image includes at least one fat image and/or at least one water image.

According to an embodiment of the computer system, the provisioning unit is designed such that the modeling data originate from further objects under examination, which are different from the object under examination, wherein the modeling data are adapted to the object under examination.

In another embodiment of the computer system, the provisioning unit is designed such that the modeling data include modeling of the distribution of adipose tissue and/or aqueous tissue.

In another embodiment of the computer system, the measured-data acquisition unit and the provisioning unit are designed such that the acquisition of the magnetic resonance measurement data includes the acquisition of at least one first magnetic resonance image with an in-phase fat-water signal and at least one second magnetic resonance image with an out-of-phase fat-water signal, wherein the modeling data includes the first magnetic resonance image and/or second magnetic resonance image.

In another embodiment of the computer system, the reconstruction unit is designed such that at least one provisional tissue image is reconstructed from the magnetic resonance measurement data, wherein the at least one provisional tissue image includes at least one provisional fat image and/or at least one provisional water image, a comparison is performed between the at least one provisional tissue image with the modeling data and the reconstruction of the at least one tissue image is performed using a result of the comparison.

According to one embodiment of the computing system, the reconstruction unit is embodied such that the reconstruction of the at least one tissue image includes an assignment of fat information and/or water information to the magnetic resonance measurement data using the modeling data.

In a further embodiment of the computer system, the provisioning unit and the reconstruction unit are designed such that the modeling data include segmentation of at least one organ in the magnetic resonance measurement data, wherein the assignment of the fat information and/or water information to the magnetic resonance measurement data is performed using the at least one segmented organ.

In another embodiment of the computer system, the provisioning unit is designed such that the modeling data include a B0 distribution of the object under examination.

In another embodiment of the computer system, the provisioning unit and the reconstruction unit are designed such that at least one provisional tissue image is reconstructed from the magnetic resonance measurement data, wherein the at least one provisional tissue image includes at least one provisional fat image and/or at least one provisional water image, a correction map is generated from the at least one provisional tissue image, a correction of the B0 distribution of the object under examination is performed using the correction map, wherein a corrected B0 distribution is calculated, an analysis of the corrected B0 distribution is performed and the reconstruction of the at least one tissue image is performed using a result of the analysis.

In another embodiment of the computer system, the provisioning unit is designed such that the modeling data include a mask marking the presence of adipose tissue or aqueous tissue in the object under examination.

In another embodiment of the computer system, the provisioning unit is designed such that the mask is generated by a spatially-resolved measurement of a resonant frequency in the object under examination.

A non-transitory computer readable data storage medium according to the invention can be loaded directly into a memory of a programmable computer of a computer system and is encoded with program code that cause the method according to the invention to be implemented by the computer system when the code is executed in the computer of the computing system. This enables the method according to the invention to be carried out quickly, identically repeatably and robustly.

The computer must satisfy certain requirements to enable the respective method steps to be carried out efficiently, such as, for example, an appropriate random access memory, an appropriate graphics card or an appropriate corresponding logic unit so that the respective method steps can be carried out efficiently. Examples of such an electronically readable data medium are a DVD, a magnetic tape or a USB stick on which electronically readable control information, in particular software (see above) is stored.

The advantages of the computer system according to the invention and of the storage medium according to the invention correspond to the advantages of the method according to the invention, which were explained in detail above. All features, advantages or alternative embodiments mentioned above 3 apply as well to the aspects of the invention. The functional features of the method are embodied by corresponding objective modules, in particular hardware modules.

### BRIEF DESCRIPTION OF THE DRAWINGS

FIG. 1 schematically illustrates a system having a magnetic resonance apparatus and a computer system according to the invention.

FIG. 2 is a flowchart of a first embodiment of a method according to the invention.

FIG. 3 is a flowchart of a second embodiment of a method according to the invention.

FIG. 4 is a flowchart of a third embodiment of a method according to the invention.

FIG. 5 is a flowchart of a fourth embodiment of a method according to the invention.

### DESCRIPTION OF THE PREFERRED EMBODIMENTS

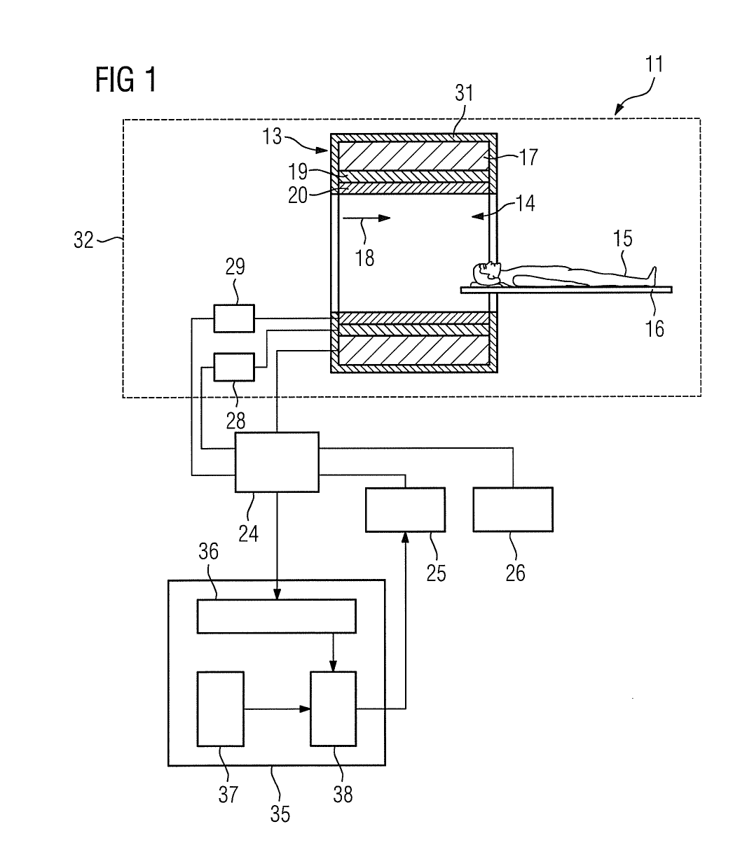

FIG. 1 is a schematic view of a system 1 having a magnetic resonance apparatus 11 and a computer system according to the invention 35.

The magnetic resonance apparatus 11 has a detector unit formed by a scanner 13 having a basic field magnet 17 that generates a strong and constant basic magnetic field 18. The magnetic resonance scanner 13 has a cylindrical patient receiving area 14 for receiving an object under examination 15, in the present case a patient, wherein the patient receiving area 14 is cylindrically enclosed by the scanner 13 in the circumferential direction. The patient 15 can be moved into the patient receiving area 14 by a patient support 16 of the magnetic resonance apparatus 11. The patient support 16 has a table that is movable inside the magnetic resonance scanner 13. The magnetic unit 13 is shielded from the outside by a housing shelf 31.

The scanner 13 further has a gradient coil arrangement 19 that generates magnetic field gradients, which are used for spatial encoding during imaging. The gradient coil arrangement 19 is controlled by a gradient control processor 28. The scanner 13 also has a radio-frequency antenna unit 20, which in the case shown is embodied as a whole body coil permanently integrated in the magnetic resonance device 10, and a radio-frequency antenna control processor 29 to excite nuclear spins in the patient 15 so as to cause the nuclear spins to deviate from the polarization that is established by the basic magnetic field 18 generated by the basic magnet 17. The radio-frequency antenna unit 20 is controlled by the radio-frequency antenna control processor 29 so as to emit radio-frequency magnetic resonance sequences into an examination volume, which is substantially formed by the patient receiving area 14. The radio-frequency antenna unit 20 is further embodied to receive magnetic resonance signals from the patient 15.

To control the basic field magnet 17, the gradient control processor 28 and the radio-frequency antenna control processor 29, the magnetic resonance apparatus 11 has a computer unit 24. The computer 24 controls the magnetic resonance apparatus 11 centrally, such as, for example, for the performance of a pre-determined imaging gradient echo sequence. Control information such as, for example, imaging parameters, and reconstructed magnetic resonance images can be provided to a user via an interface, in the present case a display unit 25 of the magnetic resonance apparatus 11. The magnetic resonance device 11 also has an input interface 26 via which information and/or parameters can be entered by a user during a measuring process. The computer 24 can include the gradient control processor 28 and/or the radio-frequency antenna control processor 29 and/or the display unit 25 and/or the input interface 26.

The magnetic resonance apparatus 11 further has an image data acquisition unit 32. The image data acquisition unit 32 is in the present case formed by the scanner 13 together with the radio-frequency antenna control processor 29 and the gradient control processor 28.

The magnetic resonance apparatus 11 that is shown can include further components that are usually present in a magnetic resonance apparatus 11. The general mode of operation of a magnetic resonance device 11 is known to the person skilled in the art known so that no detailed description of the further components will be given.

The computer system 35 according to the invention includes a measurement-data-acquisition unit 36, a provisioning unit 37 and a reconstruction unit 38. The measurement-data-acquisition unit 36 acquires magnetic resonance measurement data, which was recorded by means of the image data acquisition unit 32 of the magnetic resonance device 11. To this end, the measured-data acquisition unit 36 and the image data acquisition unit 32 are connected with respect to data exchange, in the case shown via the computing unit 24 of the magnetic resonance device 11. The at least one fat image and/or water image reconstructed by the reconstruction unit 38 from the magnetic resonance measurement data using a model can be transmitted by the reconstruction unit 38 to the display unit 25 of the magnetic resonance device 11 to be displayed. To this end, the reconstruction unit 38 is advantageously connected to the display unit 25 with respect to data exchange.

Hence, the computer system 35 is configured, together with the measurement-data-acquisition unit 36, the provisioning unit 37 and the reconstruction unit 38 to carry out a method according to the invention for the reconstruction of magnetic resonance image data. In particular it is conceivable for the computing system 35 also to carry out the method according to the invention independently of the magnetic resonance device 11 depicted. To this end, the computer system 35 can, for example, acquire magnetic resonance measurement data already recorded by means of the measurement-data-acquisition unit 36, for example by loading it out of a database. The computer system 35 can then also be connected to a separate display unit so that the at least one fat image and/or water image reconstructed by the reconstruction unit 38 can be displayed. The at least one fat image and/or water image reconstructed by the reconstruction unit 38 can also be stored directly in a database by the computing system 35 for later retrieval.

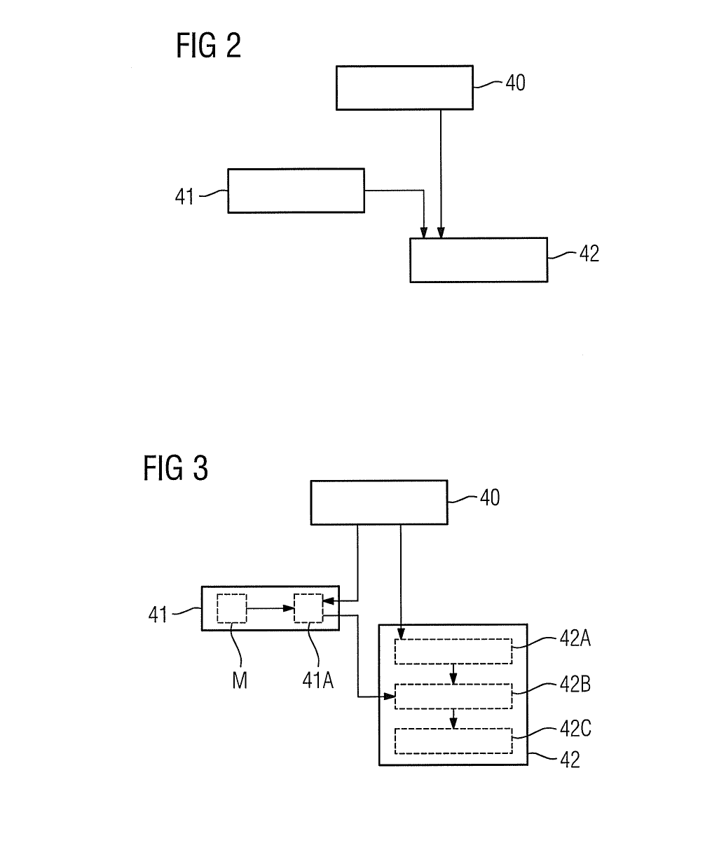

FIG. 2 is a flowchart of a first embodiment of a method according to the invention for the reconstruction of magnetic resonance image data.

In a first method step 40, the measured-data acquisition unit 36 acquires magnetic resonance measurement data of an object under examination 15 by a Dixon recording technique. To this end, the measurement-data-acquisition unit 36 can, for example, load magnetic resonance measurement data that have already been recorded by means of the Dixon recording technique from a database.

In a further method step 41, a model is provided by the provisioning unit 37, wherein the model includes modeling data, which are matched to the object under examination 15 from which the magnetic resonance measurement data is acquired. In this case, the model can in particular be loaded from a database.

In a special embodiment, the modeling data can include a mask, which marks the presence of adipose tissue or aqueous tissue in the object under examination. To this end, the mask can be generated by means of a spatially-resolved measurement of a resonant frequency in the object under examination.

In a further method step 42, at least one tissue image is reconstructed from the magnetic resonance measurement data using the model matched to the object under examination, wherein the at least one tissue image includes at least one fat image and/or at least one water image, by means of the reconstruction unit 38. The reconstructed at least one fat image and/or water image can then be made available, i.e. for example displayed to a user on the display unit 25 and/or stored in a database.

FIG. 3 is a flowchart of a second embodiment of a method according to the invention for the reconstruction of magnetic resonance image data.

The following description is substantially restricted to the differences from the exemplary embodiment in FIG. 2, wherein with regard to method steps that remain the same, reference is made to the description of the exemplary embodiment in FIG. 2. Method steps that substantially remain the same are, in principle, given the same reference numbers.

The embodiment of the method according to the invention shown in FIG. 3 substantially includes the method steps 40, 41, 42 of the first embodiment of the method according to the invention according to FIG. 2. The embodiment of the method according to the invention shown in FIG. 3 also includes additional method steps and substeps. Also conceivable is a method sequence alternative to that shown in FIG. 3, which only comprises a part of the additional method steps and/or substeps shown in FIG. 2. Obviously, a method sequence alternative to that in FIG. 3 can also comprise additional method steps and/or substeps.

Reference is made to the fact that FIGS. 3-5 show different possibilities for the taking into account the model in the reconstruction of the at least one fat image and/or water image. In this case, the procedure in FIGS. 3-5 is only shown as an example. The person skilled in the art can also use any combination of the elements and procedures shown in FIGS. 3-5.

According to embodiment shown, the model includes modeling data M, which originate from further objects under examination, which are different from the object under examination. In the exemplary embodiment shown, the further method step 41, the provision of the model, has a substep A in which the modeling data M are adapted to the object under examination 15. In this case, the adaptation of the modeling data M can include, for example, the registration of the modeling data M on the magnetic resonance measurement data recorded in the further method step 40.

The reconstruction of the at least one fat image and/or at least one water image in the further method step 42 includes an assignment of fat information and/or water information to the magnetic resonance measurement data using the model provided. Here, the modeling data include modeling of the distribution of adipose tissue and/or aqueous tissue in the further objects under examination, wherein the assignment of the fat information and/or water information to the magnetic resonance measurement data is performed using the modeling of the distribution of the adipose tissue and/or aqueous tissue. The following section describes a possible procedure for taking into account the modeling data in the reconstruction of the at least one fat image and/or water image. Further procedures that appear advisable to those skilled in the art are also conceivable.

In the case shown, in a first substep 42A of the further method step 42, at least one provisional tissue image is reconstructed from the magnetic resonance measurement data, wherein the at least one provisional tissue image includes at least one provisional fat image and/or at least one provisional water image. In a further substep 42B of the further method step 42, a comparison is performed between the at least one provisional tissue image and the model. Here, it is possible to use the modeling data M provided in the further method step 41 and adapted to the object under examination 15. For example, a comparison can be performed between the at least one provisional fat image and/or the at least one provisional water image and the modeling data M. In a further substep 42C of the further method step 42, the reconstruction of the at least one tissue image is performed using a result of the comparison.

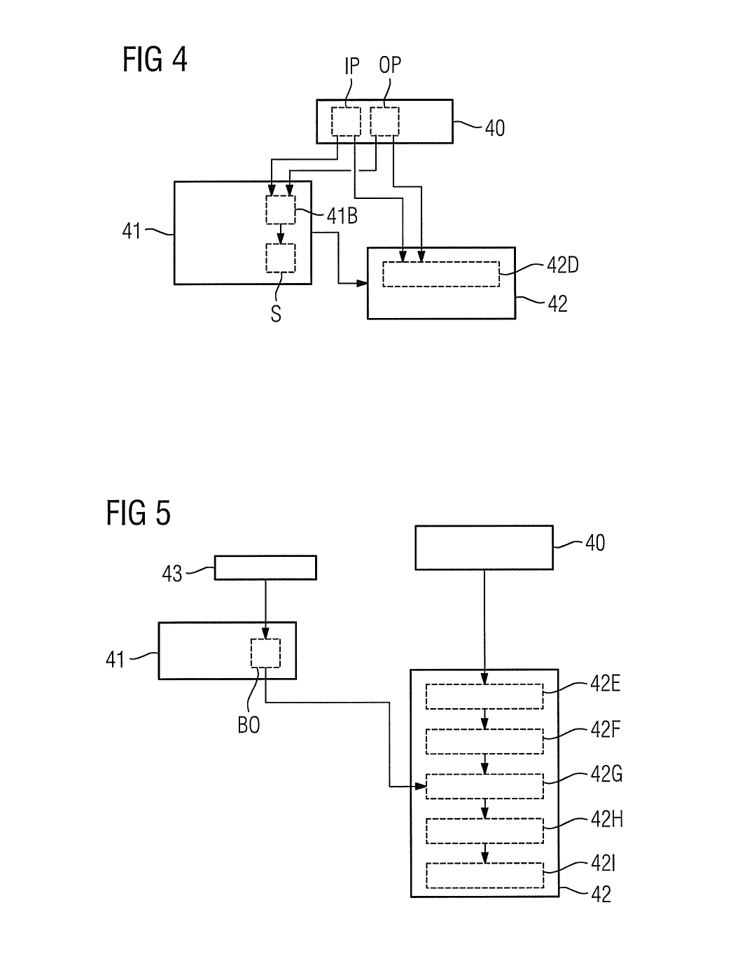

FIG. 4 is a flowchart of a third embodiment of a method according to the invention for the reconstruction of magnetic resonance image data.

The following description is substantially restricted to the differences from the exemplary embodiment in FIG. 2, reference is made to the description of the exemplary embodiment in FIG. 2 with respect to method steps that remain the same. Steps that substantially remain the same are, in principle, given the same reference numbers.

The embodiment of the method according to the invention shown in FIG. 4 includes the method steps 40, 41, 42 of the first embodiment of the method according to the invention according to FIG. 2. Additionally, the embodiment of the method according to the invention includes the additional method steps and substeps shown in FIG. 4. Also conceivable is a method sequence alternative to that shown in FIG. 4, which only comprises a part of the additional method steps and/or substeps shown in FIG. 2. The method sequence alternative to that in FIG. 4 can also include additional method steps and/or substeps.

In the exemplary embodiment shown in FIG. 4, the acquisition of the magnetic resonance measurement data includes the acquisition of at least one first magnetic resonance image IP with an in-phase fat-water signal and at least one second magnetic resonance image JO with an out-of-phase fat-water signal. This can particularly advantageously be performed by a 2-point Dixon recording technique. The at least one first magnetic resonance image IP and second magnetic resonance image JO can also be part of measured data acquired by a 3-point Dixon recording technique.

The modeling data, which was provided in the further method step 41, then includes the first magnetic resonance image IP and/or second magnetic resonance image OP. In particular, the modeling data includes the segmentation S of at least one organ in the at least one first magnetic resonance image IP and/or second magnetic resonance image OP. To this end, the further method step 41 can comprise a substep 41B in which a segmentation of the at least one organ is performed in the at least one first magnetic resonance image IP and/or second magnetic resonance image OP.

The reconstruction of the at least one tissue image in the further method step 42 includes an assignment of fat information and/or water information to the magnetic resonance measurement data using the model provided in the substep 42D of the further method step 42. The assignment of the fat information and/or water information to the magnetic resonance measurement data can be performed using the segmentation S of the at least one organ. For example, the segmentation S can serve as a starting point for the assignment of the fat information and/or water information.

FIG. 5 is a flowchart of a fourth embodiment of a method according to the invention for the reconstruction of magnetic resonance image data.

The following description substantially is substantially restricted to the differences from the exemplary embodiment in FIG. 2, wherein with regard to the methods that remain the same, reference is made to the description of the exemplary embodiment in FIG. 2. Method steps that substantially remain the same are, in principle, given the same reference numbers.

The embodiment of the method according to the invention shown in FIG. 5 substantially includes the method steps 40, 41, 42 of the first embodiment of the method according to the invention according to FIG. 2. Additionally, the embodiment of the method according to the invention shown in FIG. 5 shows additional method steps and substeps. Also conceivable is a method sequence alternative to that shown in FIG. 5, which only comprises a part of the additional method steps and/or substeps shown in FIG. 2. The method sequence alternative to that in FIG. 5 can also include additional method steps and/or substeps.

In the exemplary embodiment shown in FIG. 5, the modeling data include a B0 distribution B0 of the object under examination. This B0 distribution B0 is acquired in a further method step 43 before the acquisition of the magnetic resonance measurement data by means of a method known to the person skilled in the art. This B0 distribution B0 can then be particularly advantageously used in the further method step 42 in the reconstruction of the at least one fat image and/or water image. One procedure among several possible procedures for this is described in the following section.

In a further substep 42E of the further method step 42, at least one provisional tissue image is reconstructed from the magnetic resonance measurement data, wherein the at least one provisional tissue image includes at least one provisional fat image and/or at least one provisional water image. In a further substep 42F of the further method step 42, a correction map is generated from the at least one provisional tissue image. In a further substep 42G of the further method step 42, the B0 distribution of the object under examination is corrected using the correction map, wherein a corrected B0 distribution is calculated. In a further substep 42H of the further method step 42, the corrected B0 distribution is analyzed. In a further substep 42I of the further method step 42, the reconstruction of the at least one tissue image is performed using a result of the analysis.

The method steps of the method according to the invention shown in FIGS. 2-5 are carried out by the computer unit. For this process, the computer includes the necessary software and/or computer programs, which are stored in a storage unit of the computing unit. The software and/or computer programs include program code designed to carry out the method according to the invention when the computer program and/or the software is executed in the computing unit by a processor unit of the computer.

Although modifications and changes may be suggested by those skilled in the art, it is the intention of the inventor to embody within the patent warranted hereon all changes and modifications as reasonably and properly come within the scope of his contribution to the art.

We claim as our invention:

1. A method for reconstructing magnetic resonance image data, comprising:
operating a magnetic resonance scanner to acquire magnetic resonance measurement data from an object situated in the scanner, by executing a Dixon data acquisition technique;
providing said magnetic resonance measurement data to a computer together with a model that comprises modeling data that is matched to the object; and
in said computer, reconstructing at least one tissue image, selected from the group consisting of a fat image and a water image, of the object from the magnetic resonance measurement data using said model.

2. A method as claimed in claim 1 comprising providing said computer with said model data that originates from at least one further object that is different from said object from which said magnetic resonance measurement data were acquired, and adapting said modeling data to said object from which said magnetic resonance measurement data were acquired.

3. A method as claimed in claim 1 comprising providing said computer with said modeling data comprising a model of a distribution of at least one of adipose tissue and aqueous tissue in said object.

4. A method as claimed in claim 1 comprising operating said magnetic resonance scanner to acquire said magnetic resonance measurement data where at least one first magnetic resonance image an in-phase fat-water signal, and for at least one second magnetic resonance image with an out-of-phase fat-water signal, and comprising providing said computer with modeling data that comprises at least one of said first magnetic resonance image and said second magnetic resonance image.

5. A method as claimed in claim 1 comprising:
in said computer, reconstructing at least one provisional tissue image from said magnetic resonance measurement data, said at least one provisional tissue image being selected from the group consisting of a provisional fat image and a provisional water image;
in said computer, comparing said at least one provisional tissue image with said modeling data to obtain a comparison result; and
reconstructing said at least one tissue image dependent on said comparison result.

6. A method as claimed in claim 1 comprising reconstructing said at least one tissue image by assigning tissue information, selected from the group consisting of fat information and water information, to said magnetic resonance measurement data using said modeling data.

7. A method as claimed in claim 6 comprising providing said computer with modeling data representing a segmentation of at least one organ in said magnetic resonance measurement data, and assigning said tissue information to said magnetic resonance measurement data using the segmented organ represented by said modeling data.

8. A method as claimed in claim 1 comprising providing said computer with said model comprising modeling data representing a distribution of a basic magnetic field generated by the magnetic resonance scanner in said object.

9. A method as claimed in claim 8 comprising:
in said computer, reconstructing at least one provisional tissue image from said magnetic resonance measurement data, said at least one provisional tissue image being selected from the group consisting of a provisional fat image and a provisional water image;
in said computer, generating a correction map from said at least one provisional tissue image;
in said computer, correcting said basic magnetic field distribution of said object using said correction map in order to calculate a corrected basic magnetic field distribution in the object;
in said computer, analyzing the corrected basic magnetic field distribution?? and a analysis result; and
reconstructing said at least one tissue image dependent on said analysis result.

10. A method as claimed in claim 1 comprising providing said computer with said model comprising modeling data that represents a mask that identifies a presence of a tissue, selected from the group consisting of adipose tissue and aqueous tissue, in said object.

11. A method as claimed in claim 10 comprising providing said computer with said mask comprising said modeling data represents a mask generated by a spatially-resolved measurement of a resonant frequency in said object.

12. A magnetic resonance apparatus comprising:
a magnetic resonance scanner;
a computer configured to operate said magnetic resonance scanner to acquire magnetic resonance measurement data from an object situated in the scanner, by executing a Dixon data acquisition technique;
said computer being provided with said magnetic resonance measurement data together with a model that comprises modeling data that is matched to the object; and
said computer being configured to reconstruct at least one tissue image, selected from the group consisting of a fat image and a water image, of the object from the magnetic resonance measurement data using said model.

13. A non-transitory, computer-readable data storage medium encoded with programming instructions, said storage medium being loaded into a computer of a magnetic resonance apparatus that comprises a magnetic resonance scanner, and said programming instructions causing said computer to:
operate said magnetic resonance scanner to acquire magnetic resonance measurement data from an object situated in the scanner, by executing a Dixon data acquisition technique;
receive said magnetic resonance measurement data together with a model that comprises modeling data that is matched to the object; and
reconstruct at least one tissue image, selected from the group consisting of a fat image and a water image, of the object from the magnetic resonance measurement data using said model.
